(19) United States
(12) Patent Application Publication
(10) Pub. No.: US 2012/0114833 A1
(43) Pub. Date: May 10, 2012

(54) FILM FORMATION APPARATUS AND FILM FORMATION METHOD

(75) Inventors: Yoshiyuki Nakagawa, Chiba-shi (JP); Shingo Nakano, Chiba-shi (JP); Naoto Fukuda, Chiba-shi (JP)

(73) Assignee: CANON KABUSHIKI KAISHA, Tokyo (JP)

(21) Appl. No.: 13/281,090

(22) Filed: Oct. 25, 2011

(30) Foreign Application Priority Data
Nov. 4, 2010 (JP) 2010-247818
Sep. 28, 2011 (JP) 2011-211800

(51) Int. Cl. C23C 16/52; C23C 16/448

(52) U.S. Cl. 427/8; 118/712

(57) ABSTRACT

A film formation apparatus includes a film formation source, a quartz oscillator for measurement, and a quartz oscillator for calibration. When a thin film is formed on an object, a film forming material is heated in the source to release vapors thereof. The quartz oscillator for measurement measures the amount of the film forming material formed on the object, while the quartz oscillator for calibration calibrates the quartz oscillator for measurement. A moving part for moving the film formation source between a predetermined film formation waiting position and a predetermined film forming position with respect to the film formation object is further provided, the moving part holds the quartz oscillator for measurement so that its relative position with respect to the film formation source is maintained, and the quartz oscillator for calibration is provided above the moving part when the moving part is at the film formation waiting position.

### BACKGROUND OF THE INVENTION

1. Field of the Invention

The present invention relates to a film formation apparatus.

2. Description of the Related Art

Conventionally, when a thin film is formed on a film formation object such as a substrate by evaporation, sputtering, or the like, in order to control the thickness of the thin film to be formed, a quartz oscillator is placed in a film formation chamber. When a quartz oscillator is placed in the film formation chamber, in forming the thin film, a film forming material forming the thin film is deposited both on the quartz oscillator and on the film formation object. Here, as the film forming material is deposited on the quartz oscillator, the resonance frequency of the quartz oscillator changes according to the amount of the film forming material deposited thereon. Using this phenomenon, the thickness of the film of the film forming material deposited on the film formation object may be known. Specifically, the thickness of the film deposited on the quartz oscillator is calculated from the amount of change in resonance frequency. With the film thickness ratio between the film deposited on the quartz oscillator and the film deposited on the film formation object which is determined in advance, the thickness of the film of the film forming material deposited on the film formation object may be known.

However, as the film forming material is deposited on the quartz oscillator, the relationship between the amount of change in resonance frequency and the thickness value of the film deposited on the film formation object is deviated from the calculated values. Therefore, it is difficult to control the thickness of the film on the film formation object with accuracy for a long period of time.

Japanese Patent Application Laid-Open No. 2008-122200 discloses a method of making smaller a film thickness value error which presents a problem in controlling the thickness of a film on a film formation object. More specifically, in Japanese Patent Application Laid-Open No. 2008-122200, a method is adopted in which, in addition to a conventional quartz oscillator for measurement, a quartz oscillator for calibration is provided in the film formation chamber.

By the way, in an ordinary film formation step, first, the film formation object is brought into the film formation chamber, and a film is formed on the film formation object. Here, when the film is formed on the film formation object, the film forming material is deposited on the quartz oscillator for measurement to control the thickness of the film on the film formation object. After the film formation is completed, the film formation object is taken out of the film formation chamber, and the film formation step is completed. However, when the film formation step is repeated multiple times, the film forming material is deposited on the quartz oscillator for measurement each time the film formation step is performed, and thus, the accuracy of the film thickness control is lowered as the film formation step is repeated. Therefore, the quartz oscillator for calibration is used to carry out a calibration step.

In the film formation method disclosed in Japanese Patent Application Laid-Open No. 2008-122200, the calibration step is performed between film formation steps, that is, after a film formation step is completed and before the subsequent film formation step is started. In this calibration step, first, the film forming material is deposited both on the quartz oscillator for calibration and on the quartz oscillator for measurement. Then, the thickness of the thin film formed on the film formation object which is determined using the quartz oscillator for calibration (film thickness value P₀) and the thickness of the thin film formed on the film formation object which is determined using the quartz oscillator for measurement (film thickness value M₀) are measured, and a calibration coefficient P₀/M₀ is determined. Then, in the film formation step which is performed after the calibration step, by multiplying a film thickness value M₁ of the film formation object which is calculated using the quartz oscillator for measurement by the calibration coefficient P₀/M₀ which is determined in advance, the thickness of the film on the film formation object is controlled with accuracy.

On the other hand, Japanese Patent Application Laid-Open No. 2004-091919 discloses an apparatus and a method for forming a film having a uniform thickness on a surface of a film formation object. In the thin film formation apparatus disclosed in Japanese Patent Application Laid-Open No. 2004-091919, a movable film formation source moves with constant speed below a fixed film formation object. By forming a thin film using the thin film formation apparatus, a film having a uniform thickness may be formed on the film formation object even if the film formation object has a large area.

Further, in the thin film formation apparatus disclosed in Japanese Patent Application Laid-Open No. 2004-091919, in order to monitor the amount of the film forming material released from the film formation source, a film thickness sensor is provided which is fixed above a waiting position of the film formation source. The film thickness sensor may detect the film forming speed of the film forming material, and thus, at the time when the film forming speed reaches a desired level, the film formation source moves to a film forming position to form a film on the film formation object.

By the way, in the film formation apparatus disclosed in Japanese Patent Application Laid-Open No. 2004-091919, as described above, while the film formation source is moved, the film thickness sensor is fixed above the waiting position of the film formation source. It follows that, while the film formation source is moved, the amount of the film forming material released from the film formation source cannot be monitored. Therefore, even if the amount of the released film forming material fluctuates while the film formation source is moved, the fluctuations cannot be monitored, and thus, the amount of the released film forming material cannot be corrected to the desired release amount. Further, if the amount of the released film forming material cannot be corrected immediately, the actual amount of the released film forming material deviates from the desired release amount more and more. As a result, a problem arises that, as the process of forming a film of the film forming material on the film formation object (film formation process) is repeated, the thickness of the thin film formed on the film formation object cannot be made uniform among the film formation processes.

Further, in the film formation apparatus disclosed in Japanese Patent Application Laid-Open No. 2004-091919, even if the film thickness sensor detects an abnormality in the amount of the released film forming material when the film formation source returns to the waiting position, it takes time to correct the release amount to the desired one, and while this correction is made, the film formation object is held up in the film formation chamber. As a result, a problem arises that the productivity is lowered.

On the other hand, in the film formation apparatus disclosed in Japanese Patent Application Laid-Open No. 2008-122200, in addition to the quartz oscillator for measurement, the quartz oscillator for calibration is provided. Further, in the film formation apparatus disclosed in Japanese Patent Application Laid-Open No. 2008-122200, the calibration process is carried out between film formation processes. More specifically, the quartz oscillator for calibration is used to carry out a process of calibrating an error in the quartz oscillator for measurement (error between the thickness of the thin film of the film forming material monitored using the quartz oscillator for measurement and the thickness of the thin film of the film forming material formed on the film formation object). By carrying out the calibration process, the accuracy of controlling the thickness of the thin film formed on the film formation object is improved.

However, when the film formation source is movable and both of the quartz oscillators (quartz oscillator for measurement and quartz oscillator for calibration) are fixed, similarly to the case of the film formation apparatus disclosed in Japanese Patent Application Laid-Open No. 2004-091919, the amount of the film forming material released from the film formation source cannot be monitored while the film formation source is moved. Therefore, similarly to the case of the film formation apparatus disclosed in Japanese Patent Application Laid-Open No. 2004-091919, a problem arises that, as the process of forming a film of the film forming material on the film formation object (film formation process) is repeated, the thickness of the thin film formed on the film formation object cannot be made uniform among the film formation processes.

### SUMMARY OF THE INVENTION

The present invention has been accomplished to solve the problems described above, and an object of the present invention is to provide a film formation apparatus capable of forming a uniform film on a film formation object with accuracy.

According to a first aspect of the present invention, there is provided a film formation apparatus, which includes: an evaporation source for heating a film forming material and for releasing vapors of the film forming material; a moving part for moving the evaporation source between a predetermined film formation waiting position and a predetermined film forming position with respect to a film formation object; a quartz oscillator for measurement for measuring an amount of the film forming material formed on the film formation object; and a quartz oscillator for calibration for calibrating the amount of the film forming material measured by the quartz oscillator for measurement, wherein the quartz oscillator for measurement is provided in the moving part and the quartz oscillator for calibration is provided above the predetermined film formation waiting position of the moving part.

According to a second aspect of the present invention, there is provided a film formation method using an apparatus, including: an evaporation source for releasing vapors of a film forming material; a moving part for moving the evaporation source between a predetermined film formation waiting position and a predetermined film forming position with respect to a film formation object;

a quartz oscillator for measurement for measuring an amount of the film forming material formed on the film formation object; and a quartz oscillator for calibration for calibrating the amount of the film forming material measured by the quartz oscillator for measurement, the method including: a film forming step for depositing the film forming material on the film formation object and the quartz oscillator for measurement during the movement of the evaporation source at the film forming position; a step of measuring an amount of the film forming material formed on the film formation object with the quartz oscillator for measurement; a step of depositing the film forming material on the quartz oscillator for measurement and the quartz oscillator for calibration when the evaporation source is at the waiting position; a step of measuring an amount of the film forming material deposited on each of the quartz oscillator for measurement and the quartz oscillator for calibration with each quartz oscillator; and a step of determining a calibration coefficient for calibrating the film formation amount of the film forming material measured by the quartz oscillator for measurement based on a ratio of film formation amounts measured with the respective quartz oscillators.

According to the present invention, it is possible to provide the film formation apparatus capable of forming a uniform film on the film formation object with accuracy.

Further features of the present invention will become apparent from the following description of exemplary embodiments with reference to the attached drawings.

### BRIEF DESCRIPTION OF THE DRAWINGS

FIGS. 1A and 1B are schematic views illustrating a film formation apparatus according to an embodiment of the present invention, which are obtained when a film formation source is at a film formation waiting position, and FIGS. 1C and 1D are schematic views illustrating the film formation apparatus according to the embodiment of the present invention, which are obtained when the film formation source is at a film forming position.

FIG. 2 is a circuit block diagram illustrating a control system of the film formation apparatus illustrated in FIGS. 1A to 1D.

FIG. 3 is a flow chart illustrating a thickness control flow of a film of a film forming material formed on a film formation object.

FIG. 4 is a graph which compares the thickness of a thin film formed on the film formation object when a calibration process is carried out to that when the calibration process is not carried out.

### DESCRIPTION OF THE EMBODIMENTS

A film formation apparatus according to the present invention includes a film formation source, a quartz oscillator for measurement, and a quartz oscillator for calibration.

In the film formation apparatus according to the present invention, when a thin film of a film forming material is formed on a film formation object, the film forming material is heated in the film formation source to release vapors of the film forming material.

In the film formation apparatus according to the present invention, the quartz oscillator for measurement is provided for the purpose of measuring the amount of the film of the film forming material formed on the film formation object (thickness of the formed thin film).

In the film formation apparatus according to the present invention, the quartz oscillator for calibration is provided for the purpose of calibrating the quartz oscillator for measurement. Note that, the timing at which the quartz oscillator for calibration calibrates the quartz oscillator for measurement is arbitrary.

Further, in the film formation apparatus according to the present invention, there is further provided a moving part for moving the film formation source between a predetermined film formation waiting position and a predetermined film forming position with respect to the film formation object. The moving part holds the quartz oscillator for measurement so that its relative position with respect to the film formation source is maintained.

On the other hand, the quartz oscillator for calibration is provided above the moving part when the moving part is at the film formation waiting position.

The film formation apparatus according to the present invention is described in the following with reference to the attached drawings, but the present invention is not limited thereto. Further, appropriate modifications can be made thereto without departing from the gist of the present invention.

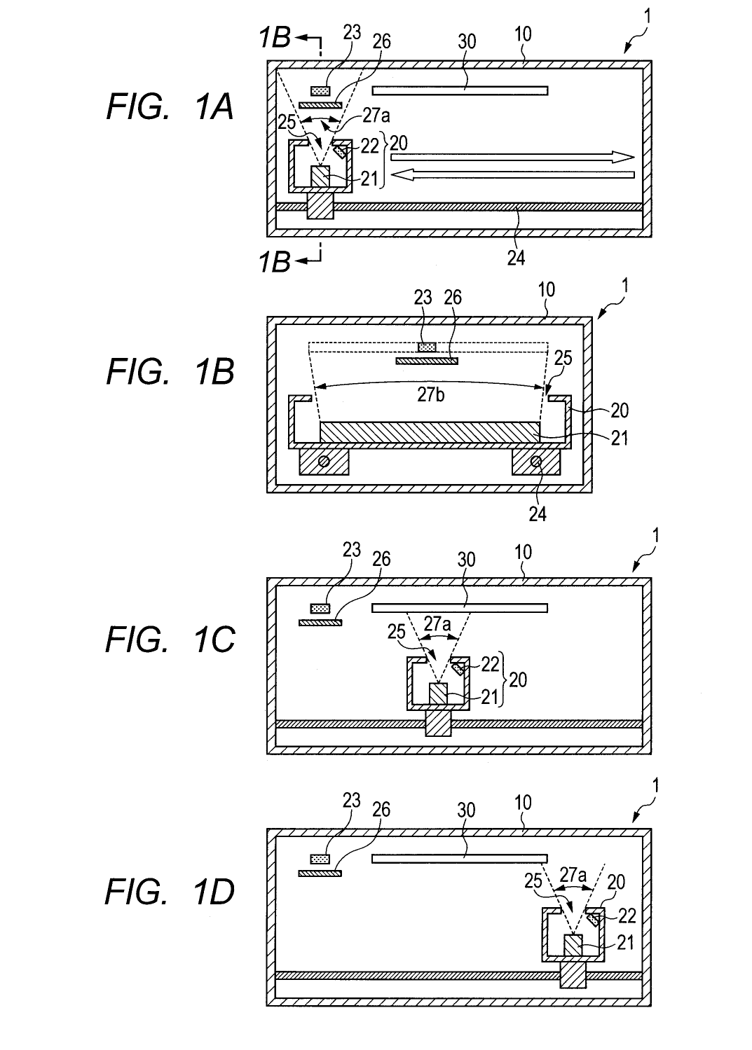

FIGS. 1A and 1B are schematic views illustrating a film formation apparatus according to an embodiment of the present invention, which are obtained when a film formation source is at a film formation waiting position, and FIGS. 1C and 1D are schematic views illustrating the film formation apparatus according to the embodiment of the present invention, which are obtained when the film formation source is at a film forming position. Note that, FIGS. 1A, 1C, and 1D are schematic sectional views of the film formation apparatus when viewed from the front side (in the width direction), and FIG. 1B is a schematic sectional view of the film formation apparatus taken along the line 1B-1B of FIG. 1A when viewed from the left side (in the depth direction).

In a film formation apparatus 1 illustrated in FIGS. 1A to 1D, a film formation source unit 20 as a moving part for moving a film formation source 21 and two kinds of quartz oscillators (quartz oscillator 22 for measurement and quartz oscillator 23 for calibration) are provided at predetermined positions in a film formation chamber 10. Note that, the positions at which the two quartz oscillators are provided are described below.

In the following, members forming the film formation apparatus 1 illustrated in FIGS. 1A to 1D are described. Note that, the film formation apparatus 1 illustrated in FIGS. 1A to 1D is used in, for example, manufacturing an organic electroluminescent (EL) element.

In the film formation apparatus 1 illustrated in FIGS. 1A to 1D, the film formation chamber 10 is connected to a vacuum exhaust system (not shown). The vacuum exhaust system may exhaust the film formation chamber 10 so that the pressure therein is in a range of 1.0×10⁻⁴ Pa to 1.0×10⁻⁶ Pa.

In the film formation apparatus 1 illustrated in FIGS. 1A to 1D, the film formation source unit 20 may reciprocate along a rail 24 provided in the film formation chamber 10 in the direction of arrows illustrated in FIG. 1A, more specifically, between the film formation waiting position and the film forming position. Here, the film formation waiting position is a position of the film formation source unit 20 when a film of the film forming material is not formed on a film formation object 30. More specifically, as illustrated in FIG. 1A, the film formation waiting position is a position of the film formation source unit 20 when the film formation object 30 is not at a position vapors of the film forming material released from the film formation source 21 may reach. On the other hand, the film forming position is a position of the film formation source unit 20 when a film of the film forming material is formed on the film formation object 30. More specifically, as illustrated in FIGS. 1C and 1D, the film forming position is a position of the film formation source unit 20 when the film formation object 30 is at a position vapors of the film forming material released from the film formation source 21 may reach.

Note that, in the present invention, the shape of the film formation source unit 20 is not specifically limited, but, from the viewpoint of selectively releasing vapors of the film forming material from a predetermined position, it is preferred that the film formation source unit 20 be a box having an opening 25 provided in an upper portion thereof for releasing vapors of the film forming material. By causing the film formation source unit 20 to be a box, the direction of travel and the distribution of vapors of the film forming material released from the film formation source unit 20 may be controlled by the shape of the opening 25. In particular, by controlling the width of the opening 25, the distribution of vapors of the film forming material and the efficiency of the film formation may be caused to be satisfactory. A preferred range of the width of the opening 25 is described below.

Further, in the present invention, the size of the film formation source unit 20 is not specifically limited. Note that, the size of the film formation source unit 20 is appropriately set taking into consideration the balance thereof with other members including the film formation chamber 10.

When the film formation source unit 20 reciprocates along the rail 24 between the film formation waiting position and the film forming position as illustrated in FIG. 1A, a movement control part (not shown) may be provided in the film formation source unit 20. In particular, if the movement control part may move the film formation source unit 20 with constant speed, a film of the film forming material may be uniformly formed on the film formation object 30, which is preferred.

The shape of the film formation source 21 provided in the film formation source unit 20 may be appropriately set taking into consideration the size of the film formation object 30 and the distribution of vapors of the film forming material. For example, as illustrated in FIGS. 1A and 1B, the film formation source 21 may be in the shape of a rectangular parallelepiped having a dimension in a width direction of the film formation chamber 10 (in a direction of movement of the film formation source unit) which is smaller than that in a depth direction of the film formation chamber 10 (in a direction perpendicular to the direction of movement of the film formation source unit within a horizontal plane), but the present invention is not limited thereto. Further, multiple film formation sources 21 may be provided in the film formation source unit 20. The film forming material (not shown) is housed in the film formation source 21 which is provided in the film formation source unit 20. By heating the film forming material with a heating part (not shown) provided in the film formation source 21, vapors of the film forming material may be released from the film formation source 21.

According to the present invention, the quartz oscillator 22 for measurement is provided in the film formation source unit 20. Here, the quartz oscillator 22 for measurement is fixed at a predetermined position in the film formation source unit 20, more specifically, at a position at which the quartz oscillator 22 for measurement does not block vapors of the film forming material moving toward the film formation object 30. Therefore, the relative position of the quartz oscillator 22 for measurement with respect to the film formation source 21 is always maintained at the predetermined position. In other words, the relative position of the film formation source 21 and the quartz oscillator 22 for measurement is always fixed. To maintain the positional relationship between the film formation source 21 and the quartz oscillator 22 for measurement in this way is important in monitoring the amount of vapors of the film forming material released from the film formation source 21 using the quartz oscillator 22 for measurement. Further, by providing the quartz oscillator 22 for measurement in the film formation source unit 20, the amount of vapors of the film forming material released from the film formation source 21 may be always monitored. Therefore, even while the film formation source unit 20 is moved, the amount of vapors of the film forming material may be adjusted according to the monitored value using the quartz oscillator 22 for measurement and the amount of the film forming material released from the film formation source 21 may be controlled to be constant.

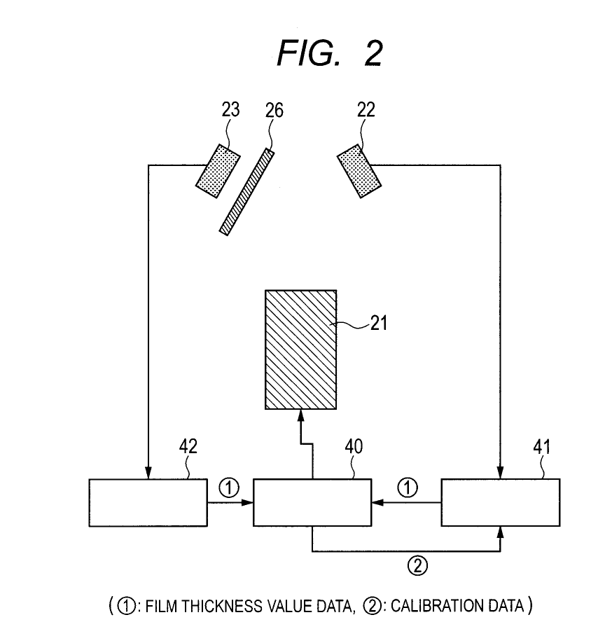

By the way, the deposition of the film forming material on the quartz oscillator 22 for measurement changes the resonance frequency of the quartz oscillator 22 for measurement. FIG. 2 is a circuit block diagram illustrating a control system of the film formation apparatus illustrated in FIGS. 1A to 1D. As illustrated in FIG. 2, the amount of change in resonance frequency of the quartz oscillator 22 for measurement is sensed by a film thickness measurement device 41. Then, an electrical signal which is output from the film thickness measurement device 41 (electrical signal concerning information of the amount of change in resonance frequency of the quartz oscillator 22 for measurement) is sent to a thermoregulator (not shown) provided in a control system 40 to control the heating part of the film formation source 21, for example, to adjust the heating temperature of the film forming material. In this way, the amount of the film forming material released from the film formation source 21 is controlled to be constant.

The quartz oscillator 23 for calibration is provided above the film formation source unit 20 when the film formation source unit 20 is stopped at the film formation waiting position. More specifically, the quartz oscillator 23 for calibration is provided at a position vapors of the film forming material released from the film formation source 21 may reach when the film formation source unit 20 is stopped at the film formation waiting position. Here, when the quartz oscillator 23 for calibration is provided, it is preferred that the quartz oscillator 23 for calibration be provided at a position at which the distance between the quartz oscillator 23 for calibration and the film formation source 21 (distance in the vertical direction) is equal to the distance between the film formation object 30 and the film formation source (distance in the vertical direction). In other words, the positional relationship between the film formation source 21 and the quartz oscillator 23 for calibration in the calibration process may be caused to be equal to the positional relationship between the film formation source 21 and the film formation object 30 in the film formation process. This may cause the amount of the film forming material jetted onto the quartz oscillator 23 for calibration per unit area to be equal to the amount of the film forming material jetted onto the film formation object 30 per unit area, and thus, the accuracy of the calibration may be further improved.

By the way, the deposition of the film forming material on the quartz oscillator 23 for calibration changes the resonance frequency of the quartz oscillator 23 for calibration. As illustrated in FIG. 2, the amount of change in resonance frequency of the quartz oscillator 23 for calibration due to the deposition of the film forming material is sensed by a film thickness measurement device 42. Then, an electrical signal which is output from the film thickness measurement device 42 (electrical signal concerning information of the amount of change in resonance frequency of the quartz oscillator 23 for calibration) is sent to the control system 40, and is then sent to the quartz oscillator 22 for measurement to calibrate the quartz oscillator 22 for measurement.

In the film formation apparatus 1 illustrated in FIGS. 1A to 1D, a sensor shutter 26 is provided in proximity to the quartz oscillator 23 for calibration. By providing the sensor shutter 26, the film forming material may be caused to attach to the respective quartz oscillators at a predetermined timing and vapors of the film forming material may be blocked at a predetermined timing.

By the way, by controlling the size and the width of the opening 25 in the film formation source unit 20, the range which vapors of the film forming material released from the film formation source 21 reach may be controlled. Here, while the film formation source unit 20 stands still at the film formation waiting position, the quartz oscillator 23 for calibration is provided in the range which vapors of the film forming material released from the film formation source 21 reach. By providing the quartz oscillator 23 for calibration in this range which vapors reach, even if the amount of the released vapors of the film forming material changes and the distribution of the released vapors changes, the ratio of the film forming material jetted onto the film formation object 30 per unit area to the film forming material jetted onto the quartz oscillator 23 for calibration per unit area remains the same. Therefore, the change in thickness of the thin film formed on the film formation object 30 may be detected with accuracy. As a result, the accuracy of the calibration is improved.

Here, when the opening 25 is in the shape of an elongated rectangle as in the film formation source unit 20 in the film formation apparatus 1 illustrated in FIGS. 1A to 1D, the range which vapors of the film forming material released from the film formation source 21 reach is defined as follows.

Specifically, in a short side direction of the opening 25 (FIG. 1A), the above-mentioned range is a range between a straight line passing through the center of the film formation source 21 and a left end of the opening 25 and a straight line passing through the center of the film formation source 21 and a right end of the opening 25, and is defined by an angle 27a formed therebetween. Here, the angle 27a is preferably in a range of 5° to 60°, more preferably in a range of 15° to 30°. If the angle 27a is smaller than 5°, the film forming material is liable to attach to the opening 25, in particular, to the ends of the opening 25, which may result in lowered film formation efficiency. If the angle 27a is larger than 60°, the distribution of vapors of the film forming material released from the film formation source 21 becomes excessively wide, and there is a fear that, even when the film formation source unit 20 stands still at the film formation waiting position, part of vapors of the film forming material may attach to the film formation object 30.

On the other hand, in a long side direction of the opening 25, the above-mentioned range is a range defined by an angle 27b of FIG. 1B.

Further, in the film formation apparatus 1 illustrated in FIGS. 1A to 1D, the sensor shutter 26 is provided in proximity to the quartz oscillator 23 for calibration, but the present invention is not limited thereto. For example, another sensor shutter 26 may be additionally provided in proximity to the quartz oscillator 22 for measurement.

In the film formation apparatus 1 illustrated in FIGS. 1A to 1D, the film formation object 30 such as a substrate is brought into the film formation chamber 10 and is taken out of the film formation chamber 10 by a transport mechanism (not shown). When the film formation object 30 is brought into the film formation chamber 10, a support member (not shown) is used to support the film formation object 30 at a predetermined position.

Next, a specific example of a film formation method using the film formation apparatus according to the present invention is described.

First, as a preliminary stage of the film formation, a preliminary step of measuring the thickness of a film deposited on the quartz oscillator 22 for measurement per unit time, the thickness of a film deposited on the quartz oscillator 23 for calibration per unit time, and the thickness of a film deposited on the film formation object 30 and determining a film thickness ratio based on the measured values is performed.

In this preliminary step, first, the film formation object 30 is brought into the film formation chamber 10 by the transport mechanism (not shown). Then, at the time when the amount of the film forming material released from the film formation source 21 which is measured at the film formation waiting position using the quartz oscillator 22 for measurement reaches a desired level, movement of the film formation source unit 20 is started and a thin film of the film forming material is formed on the film formation object 30. After reciprocating the film formation source unit 20 a predetermined number of times under predetermined movement conditions, the transport mechanism (not shown) is used to take the film formation object 30 out of the film formation chamber 10.

With regard to the thin film formed on the film formation object 30 which has been taken out here, the thickness of the thin film is measured using an optical film thickness measurement device or a contact film thickness measurement device. The measured value (film thickness value) is assumed to be t. On the other hand, the thickness of the thin film deposited on the quartz oscillator 22 for measurement per unit time when the film of the film forming material is formed on the film formation object 30 may be calculated from the amount of change in resonance frequency of the quartz oscillator 22 for measurement. Here, the thickness of the thin film deposited on the quartz oscillator 22 for measurement per unit time (film thickness value) is assumed to be M. Then, the ratio αof t to M (film thickness ratio) is expressed as α=t/M.

The quartz oscillator 23 for calibration also measures the amount of vapors deposited per unit time, and a thickness P of the thin film formed on the quartz oscillator 23 for calibration per unit time (film thickness value) is calculated from the amount of change in resonance frequency of the quartz oscillator 23 for calibration. Then, the ratio of t to P (film thickness ratio) β is determined by β=t/P. Note that, simultaneously with the formation of the thin film on the quartz oscillator 23 for calibration, a thin film of the film forming material is also formed on the quartz oscillator 22 for measurement. The thickness of the thin film formed here on the quartz oscillator 22 for measurement (film thickness value) is assumed to be M′. Then, β may be expressed as β=α×M′/P.

Here, when the amount of vapors is measured using the quartz oscillator 23 for calibration, it is preferred that excess deposition of the film forming material on the quartz oscillator 23 for calibration be prevented by, for example, using the sensor shutter 26. This may lengthen the time period during which the accuracy of measuring the film thickness provided by the quartz oscillator 23 for calibration remains high.

After the film thickness ratios α and β are determined as described above, the film formation step of forming a film of the film forming material on the film formation object 30 is performed.

In the film formation step, first, a substrate which is the film formation object 30 (for example, substrate including a TFT to be used for manufacturing an organic EL display device) is brought into the film formation chamber 10. Then, the film formation source unit 20 is caused to reciprocate under predetermined conditions between the film formation waiting position and the film forming position and the film of the film forming material is formed on the film formation object 30. After the film formation is completed, the film formation object 30 is taken out of the film formation chamber 10. By repeating the film formation step, a film of the film forming material may be formed on multiple film formation objects 30.

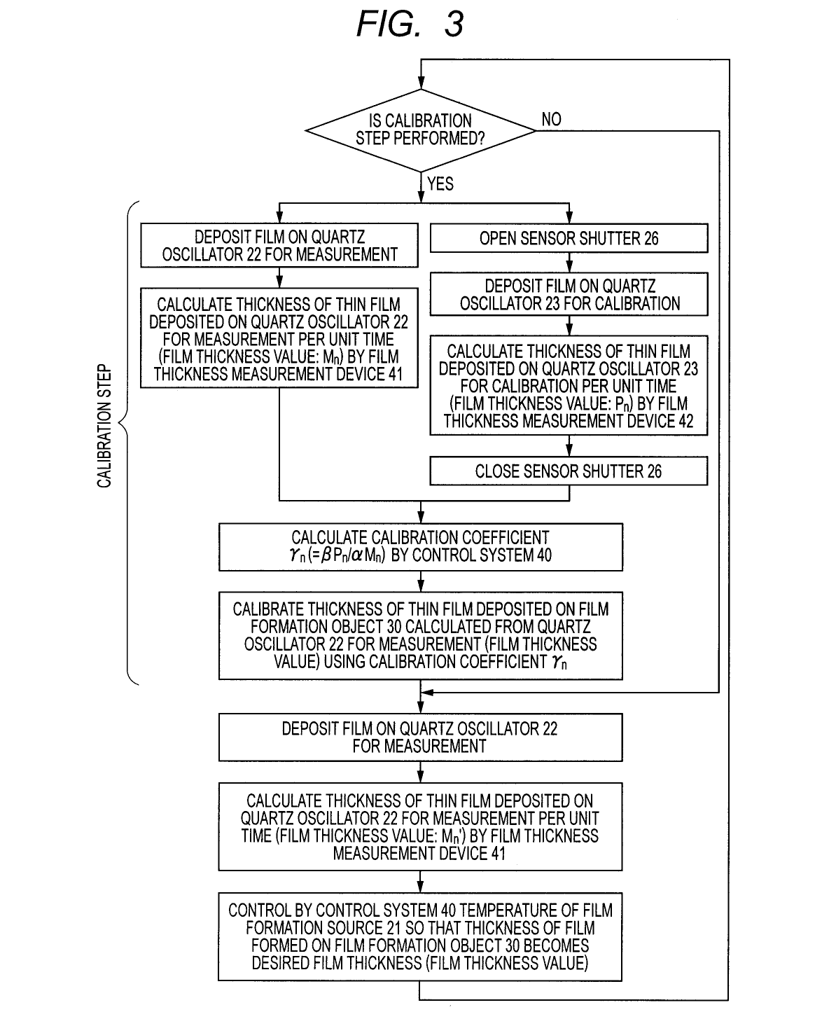

FIG. 3 is a flow chart illustrating a thickness control flow of the film of the film forming material formed on the film formation object 30. Note that, in the flow chart illustrated in FIG. 3, a flow chart illustrating the calibration step is also included. In the following, description is made also with reference to the circuit block diagram of FIG. 2.

First, when the calibration step is not performed, while the sensor shutter 26 in proximity to the quartz oscillator 23 for calibration is closed, the film forming material is deposited on the quartz oscillator 22 for measurement. Here, the film thickness measurement device 41 electrically connected to the quartz oscillator 22 for measurement measures the amount of change in resonance frequency of the quartz oscillator 22 for measurement. From the amount of change in resonance frequency measured by the film thickness measurement device 41, a film thickness value M₀′ of the film deposited on the quartz oscillator 22 for measurement per unit time is calculated in the film thickness measurement device 41. Then, the film thickness measurement device 41 sends the film thickness value M₀′ to the thermoregulator (not shown) provided in the control system 40 which is electrically connected thereto, and determines the thickness of the thin film deposited on the film formation object 30, that is, a film thickness value t₀ (=α×M₀′). Here, if t₀ is larger than a desired film thickness, an electrical signal is sent from the film thickness measurement device 41 to the thermoregulator (not shown) provided in the control system so that the thermoregulator lowers the temperature of the film formation source 21. On the other hand, if t₀ is smaller than the desired film thickness, an electrical signal is sent from the film thickness measurement device to the thermoregulator so that the thermoregulator raises the temperature of the film formation source 21. When t₀ is equal to the desired film thickness, an electrical signal is sent from the film thickness measurement device 41 to the thermoregulator so that the thermoregulator maintains the temperature of the film formation source 21. Note that, as described above, the relative positional relationship between the quartz oscillator 22 for measurement and the film formation source 21 does not change at any time, and thus, even when the film formation source unit 20 is moving, the film thickness value M₀′ may be always monitored and the temperature of the film formation source 21 may be always controlled. Therefore, the amount of the film forming material released from the film formation source 21 may be held constant.

However, during operation of the film formation source 21, the film forming material is deposited on the quartz oscillator 22 for measurement at all times, and thus, the accuracy of measuring the film thickness is gradually lowered. In such a case, the calibration step described below is performed.

In the calibration step, the sensor shutter 26 in proximity to the quartz oscillator 23 for calibration is opened at an arbitrary timing during a film formation waiting step, that is, between a film formation step and a subsequent film formation step. Here, by causing the sensor shutter 26 to be open for a predetermined period of time or longer, a fixed amount of the film forming material is deposited on the quartz oscillator 23 for calibration, and thus, the thickness of the thin film formed on the quartz oscillator 23 for calibration per unit time (film thickness value P₁) may be determined. At the same time, the thickness of the thin film formed on the quartz oscillator 22 for measurement per unit time (film thickness value M₁) may be determined. After the film thickness values P₁ and M₁ are determined, the sensor shutter 26 is closed. Here, the thickness of the thin film formed on the film formation object 30 (film thickness value) may be determined as βP₁ using the film thickness value P₁, and also may be determined as βM₁ using the film thickness value M₁.

By the way, the quartz oscillator 23 for calibration is used only in the calibration process which is carried out at an arbitrary timing when the measurement error of the quartz oscillator 22 for measurement becomes large, and thus, the amount of the film of the film forming material deposited on the quartz oscillator 23 for calibration is extremely small and the thickness measurement error is small. On the other hand, the quartz oscillator 22 for measurement is used for monitoring the amount of vapors at all times while vapors are released from the film formation source 21, and thus, a large amount of the film forming material is deposited on the quartz oscillator 22 for measurement and the thickness measurement error is large. Therefore, it does not necessarily follow that βP₁=αM₁. Therefore, the film thickness value M₁ is multiplied by a correction factor (βP₁/αM₁). Then, the film thickness value determined using the quartz oscillator for measurement may be caused to be equal to a film thickness value (βP₁) determined using the quartz oscillator 23 for calibration which has a smaller error, and thus, the film thickness value may be determined with only a small error.

After the calibration step, a film thickness value M₁′ of the film forming material deposited on the quartz oscillator 22 for measurement is determined. Then, the temperature of the film formation source 21 is controlled by the thermoregulator (not shown) provided in the control system 40 so that a value αγ₁M₁′ obtained by multiplying M₁′ by a calibration coefficient γ₁(=(βP₁)/(αM₁)) and α is the desired film thickness value to be deposited on the film formation object 30.

The calibration step is appropriately performed as described above. In the film formation step which is performed after an n-th calibration step, the film forming material is deposited on the quartz oscillator 22 for measurement and a film thickness value Mₙ′ of the film forming material deposited per unit time is determined in the film thickness measurement device 41. Then, the temperature of the film formation source 21 is controlled by the thermoregulator (not shown) provided in the control system 40 so that a value α×(γ₁×γ₂× . . . ×γₙ)×Mₙ′ obtained by multiplying Mₙ′ by a calibration coefficient (γ₁×γ₂× . . . ×γₙ) and a is the desired film thickness value to be deposited on the film formation object 30.

The calibration step may be performed at an arbitrary timing based on the premise that the calibration step is performed in the middle of the film formation waiting step, but may be performed every time a predetermined length of time passes, or may be performed every time the number of the film formation objects on which the film is formed reaches a predetermined number which is more than one. Further, the calibration step may be performed at the time when the amount of attenuation of the resonance frequency of the quartz oscillator 22 for measurement reaches a constant level, and may be performed at the time when the resonance frequency of the quartz oscillator 22 for measurement reaches a certain value.

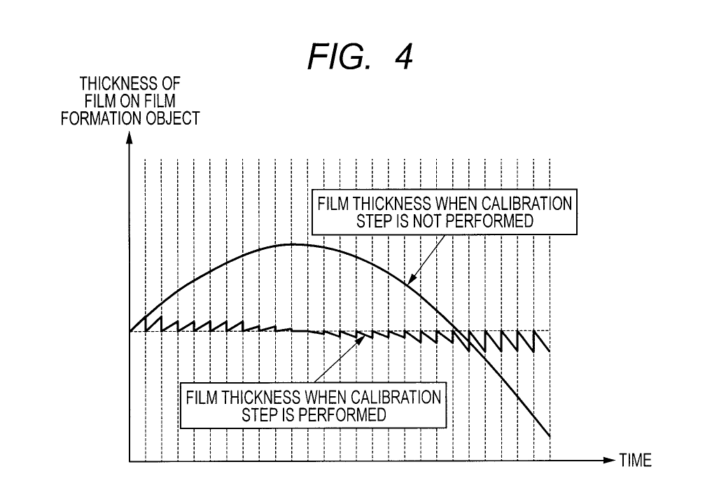

FIG. 4 is a graph which compares the thickness of the thin film formed on the film formation object 30 when the calibration step is performed to that when the calibration step is not performed. It is made clear that, as illustrated in FIG. 4, by appropriately carrying out the calibration step, the error in thickness of the film formed on the film formation object 30 may be reduced.

As described above, in the film formation apparatus according to the present invention, as illustrated in, for example, the film formation apparatus 1 of FIGS. 1A to 1D, by providing the film formation source and the quartz oscillator 22 for measurement at the predetermined positions in the film formation source unit 20, the amount of the film forming material released from the film formation source 21 may be held constant. This further enables formation of a uniform thin film on the film formation object 30. Further, by providing the quartz oscillator 23 for calibration at the predetermined position to calibrate the thickness of the thin film of the film forming material monitored using the quartz oscillator 22 for measurement (film thickness value), film formation with high film thickness accuracy may be carried out.

### EXAMPLE

### Example 1

The film formation apparatus illustrated in FIGS. 1A to 1D was used to form the film of the film forming material on the substrate.

In this example, the film was formed by reciprocating once the film formation source unit 20 with the transport distance being 1,000 mm and with the transport speed being 5 mm/s. The dimension of the substrate (film formation object 30) was 500 mm (longitudinal direction)×400 mm, and the thickness of the substrate was 0.5 mm.

Further, in this example, the heating temperature of the film formation source 21 was adjusted so that the thickness of the thin film of the film forming material formed on the substrate (film formation object 30) was 100 nm.

Further, in this example, as the quartz oscillator 22 for measurement and the quartz oscillator 23 for calibration, 6 MHz quartz oscillators having gold electrodes and manufactured by INFICON were used.

In this example, the distance between the film formation source 21 and the substrate (film formation object 30) was 300 mm, and the distance between the film formation source 21 and the quartz oscillator 23 for calibration obtained when the film formation source 21 was at the film formation waiting position was 300 mm.

First, the preliminary step of the film formation was performed.

In this preliminary process step, first, the substrate (film formation object 30) for measuring the film thickness was brought into the film formation chamber 10. After confirming that the amount of vapors of the film forming material released from the film formation source 21 had been stabilized at a desired value, movement of the film formation source unit 20 was started at a transport speed of 5 mm/s.

Here, the thickness of the thin film formed on the quartz oscillator 22 for measurement during 1 minute obtained when the film formation source unit 20 was moved in a film forming region (film thickness value: M (nm)) was determined. Then, after a film was formed under predetermined film formation conditions, a substrate transport mechanism (not shown) was used to take the substrate (film formation object 30) out of the film formation chamber 10. Then, the thickness of the thin film formed on the substrate (film formation object 30) which was taken out (film thickness value: t (nm)) was measured using an optical film thickness measurement device or a contact film thickness measurement device. Then, the ratio a of the thickness value of the film deposited on the substrate during 1 minute to the thickness value of the film deposited on the quartz oscillator 22 for measurement during 1 minute was expressed as α=t/M.

Next, the ratio of the thickness of the thin film formed on the substrate (film formation object 30) during 1 minute (film thickness value) to the thickness of the thin film formed on the quartz oscillator 23 for calibration during 1 minute (film thickness value) was determined. More specifically, after the film of the film forming material was formed on the substrate (film formation object 30), the film formation source unit 20 was stopped at the film formation waiting position. At the time when ten seconds passed after the stop, the sensor shutter 26 was opened to cause a thin film of the film forming material to be formed on the quartz oscillator 23 for calibration. Then, the thickness of a thin film formed on the quartz oscillator 23 for calibration during 1 minute from the time when 30 seconds passed to the time when 90 seconds passed after the sensor shutter 26 was opened (film thickness value: P (nm)) was determined. Meanwhile, during this time period (during 1 minute from the time when 30 seconds passed to the time when 90 seconds passed after the sensor shutter 26 was opened), a thin film of the film forming material was also formed on the quartz oscillator 22 for measurement. Therefore, the thickness of the thin film formed on the quartz oscillator 22 for measurement during this time period (film thickness value: M′ (nm)) was determined. Here, the ratio of the thickness of the thin film formed on the substrate (film formation object 30) during 1 minute to the thickness of the thin film formed on the quartz oscillator 22 for measurement during 1 minute is assumed to be β. Then, β may be expressed as β=α×M′/P. At the time when 91 seconds passed after the sensor shutter 26 was opened, the sensor shutter 26 was closed to prevent film formation on the quartz oscillator 23 for calibration. Note that, in the preliminary process step, M=M′ and the film thickness value t (nm) satisfied the relational expression of t=αM=βP.

Then, the step proceeded to the film formation step. In the film formation step, first, the substrate which was the film formation object 30 was brought into the film formation chamber 10. After the substrate was brought in, movement of the film formation source unit 20 was started. After the movement of the film formation source unit 20 was completed, the substrate was taken out of the film formation chamber 10 and the film formation step was completed.

As the film formation step was performed multiple times, films were deposited on the quartz oscillator 22 for measurement, and thus, the film thickness measurement error gradually became larger. Therefore, the calibration step described below was performed.

A first calibration process was carried out after a tenth film formation process. More specifically, at the time when ten seconds passed after the film formation source unit 20 reached the film formation waiting position from the film forming position and the film formation source unit 20 was stopped at the film formation waiting position, the sensor shutter 26 was opened. Then, a thickness of the thin film formed on the quartz oscillator for measurement (film thickness value: M₁ (nm)) and a thickness of the thin film formed on the quartz oscillator 23 for calibration (film thickness value: P₁ (nm)) from the time when 30 seconds passed to the time when 90 seconds passed after the sensor shutter 26 was opened were measured. Then, the thickness of the thin film formed on the substrate (film formation object 30) (film thickness value) was αM₁ (nm) or βP₁ (nm). However, the film thickness value αM₁ (nm) determined from the thickness of the thin film formed on the quartz oscillator 22 for measurement had a large error while the film thickness value βP₁ (nm) determined from the thickness of the thin film formed on the quartz oscillator 23 for calibration had a small error. Therefore, it did not necessarily follow that αM1=βP1. Therefore, the calibration coefficient γ₁=(βP₁)/(αM₁) was determined. In the film formation process after the calibration coefficient γ₁ was determined, the heating temperature of the film formation source 21 was adjusted so that the film thickness value M₁′ of the thickness of the film deposited on the quartz oscillator 22 for measurement during 1 minute multiplied by the calibration coefficient γ₁ and the film thickness ratio α (α×γ₁×M₁′) was the desired film thickness of 100 nm to be deposited on the substrate.

Meanwhile, in the middle of the first calibration process described above, the tenth substrate was taken out and an eleventh substrate was brought in. Immediately after the calibration process was completed, film formation on the eleventh substrate was started.

As described above, the film formation step and the calibration step were performed. In the n-th calibration step which was performed after the 10n-th film formation step, the thicknesses of the thin films formed on the respective quartz oscillators were determined. More specifically, a thickness of the film of the film forming material formed on the quartz oscillator 23 for calibration during 1 minute (film thickness value: Pₙ (nm)) and a thickness of the film of the film forming material formed on the quartz oscillator 22 for measurement during 1 minute (film thickness value: Mₙ (nm)) were determined. Then, the calibration coefficient γₙ was determined as γₙ=(βPₙ)/(αMₙ). In the film formation step after the calibration coefficient γₙ was determined, the heating temperature of the film formation source 21 was adjusted so that the film thickness of the film of the film forming material formed on the quartz oscillator 22 for measurement during 1 minute (film thickness value Mₙ′) multiplied by the calibration coefficients determined in the first to the n-th calibration steps and the film thickness ratio α, that is, α×(γ₁×γ₂× . . . ×γₙ)×Mₙ′ was 100 (nm). Note that, as described above, the heating temperature of the film formation source was changed after the movement of the film formation source unit 20 was completed.

As a result of such film formation, it was made clear that film formation was able to be performed with the film thickness being accurate.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application Nos. 2010-247818, filed Nov. 4, 2010, and 2011-211800, filed Sep. 28, 2011, which are hereby incorporated by reference herein in their entirety.

What is claimed is:

1. A film formation apparatus, comprising:
an evaporation source for heating a film forming material and for releasing vapors of the film forming material;
a moving part for moving the evaporation source between a predetermined film formation waiting position and a predetermined film forming position with respect to a film formation object;
a quartz oscillator for measurement for measuring an amount of the film forming material formed on the film formation object; and
a quartz oscillator for calibration for calibrating the amount of the film forming material measured by the quartz oscillator for measurement,
wherein the quartz oscillator for measurement is provided in the moving part and the quartz oscillator for calibration is provided above the predetermined film formation waiting position of the moving part.

2. A film formation method using an apparatus, including:
an evaporation source for releasing vapors of a film forming material;
a moving part for moving the evaporation source between a predetermined film formation waiting position and a predetermined film forming position with respect to a film formation object;
a quartz oscillator for measurement for measuring an amount of the film forming material formed on the film formation object; and
a quartz oscillator for calibration for calibrating the amount of the film forming material measured by the quartz oscillator for measurement, the method comprising:
a film forming step for depositing the film forming material on the film formation object and the quartz oscillator for measurement during the movement of the evaporation source at the film forming position;
a step of measuring an amount of the film forming material formed on the film formation object with the quartz oscillator for measurement;
a step of depositing the film forming material on the quartz oscillator for measurement and the quartz oscillator for calibration when the evaporation source is at the waiting position;
a step of measuring an amount of the film forming material deposited on each of the quartz oscillator for measurement and the quartz oscillator for calibration with each quartz oscillator; and
a step of determining a calibration coefficient for calibrating the film formation amount of the film forming material measured by the quartz oscillator for measurement based on a ratio of film formation amounts measured with the respective quartz oscillators.
